(19) United States
(12) Patent Application Publication
(10) Pub. No.: US 2026/0216757 A1
(43) Pub. Date: Jul. 30, 2026

(54) SUBSTRATE PROCESSING APPARATUS

(71) Applicants: ACM RESEARCH (SHANGHAI), INC., Shanghai (CN); ACM Research (Lingang), Inc., Shanghai (CN)

(72) Inventors: Rong Xu, Shanghai (CN); He Wang, Shanghai (CN); Jun Wang, Shanghai (CN); Hui Wang, Shanghai (CN); Xuefei Deng, Shanghai (CN); Shena Jia, Shanghai (CN); Xiaoyan Zhang, Shanghai (CN)

(73) Assignees: ACM RESEARCH (SHANGHAI), INC., Shanghai (CN); ACM Research (Lingang), Inc., Shanghai (CN)

(21) Appl. No.: 19/142,127

(22) PCT Filed: Dec. 1, 2023
(86) PCT No.: PCT/CN2023/135761

§ 371 Date: Jun. 20, 2025

(30) Foreign Application Priority Data
Dec. 19, 2022 (CN) 202211638609.2

(51) Int. Cl. B08B 3/10; H10P 72/00

(52) U.S. Cl. CPC B08B 3/102; H10P 72/0416; H10P 72/0426

(57) ABSTRACT

A substrate processing apparatus includes a processing tank. A bubbler is disposed in the processing tank and positioned below the plurality of substrates, for supplying bubbles into the processing liquid. The bubbler comprises a bubble plate facing the plurality of substrates and a bubble chamber. The bubble plate has a plurality of opening holes thereon, and the bubble chamber is used for supplying gas to the plurality of opening holes. In the present invention, the inside of the bubble chamber is divided into at least two gas channels in which the flow rate of gas supply is independently controlled and/or the bubble plate is divided into at least two opening hole regions in which the opening hole densities are independently set.

### FIELD OF THE INVENTION

The present invention relates to the field of semiconductor manufacturing equipment, and more particularly to a substrate processing apparatus.

### BACKGROUND

In the semiconductor manufacturing process, a substrate processing apparatus may simultaneously perform a process such as cleaning or etching on a plurality of substrates with processing liquid by immersing the plurality of substrates in a processing tank. In order to improve the uniformity of substrate liquid processing, for example, the etching uniformity of the substrate, a bubble supply pipe is usually arranged in the processing tank. The bubbles are supplied into the processing liquid, and the processing liquid is stirred to promote the efficiency of quality transfer on the surface of the substrate, thereby improving the uniformity of substrate etching.

For example, in the substrate processing apparatus disclosed in Patent Document 1 (CN114446822A), a plurality of bubble generating pipes are disposed below a plurality of substrates immersed in the processing liquid. The plurality of bubble generating pipes extend along the normal direction (i.e., the arrangement direction of the substrates) of the main surfaces of a plurality of substrates, and the amount of bubbles generated from the plurality of bubble generating pipes is controlled to be substantially equal by controlling the gas flow in the respective bubble generating pipes, thereby suppressing the processing non-uniformity in the entire surface of the substrates.

However, Patent Document 1 still has a problem of non-uniformity in the surface of the substrates because the bubbles are mainly concentrated in the region above the bubble generating pipes, that is, the coverage region of the bubbles generated by the bubble generating pipes on the substrates is limited. As shown in FIG. 28, there are basically no bubbles or the number of bubbles is obviously insufficient in the region indicated by the dashed box on the substrate, which will reduce the etching efficiency of local regions of the substrate, and thus make it difficult to control the in-surface uniformity of the substrate. This situation is more obvious when concave-convex structures are formed on the surface of the substrate.

For example, in the substrate processing apparatus disclosed in Patent Document 2 (CN111430270A), a fluid supply portion having a plurality of ejection paths for discharging the fluid in different regions in the arrangement directions of a plurality of substrates is disposed below the plurality of substrates. And a moving mechanism is disposed for a plurality of ejection paths, so that the ejection positions of a plurality of ejection paths are changed during the substrate liquid processing. Hence, the uniformity of processing among the plurality of substrates and the uniformity in the entire surface of the substrates can be improved.

However, in Patent Document 2, the in-surface and inter-sheet uniformity of the substrate liquid processing is realized by the moving mechanism, which makes the configuration and control of the apparatus complicated, the cost increases, and the maintenance difficulty increases.

### SUMMARY

A technical problem of the present invention is to provide a substrate processing apparatus capable of improving the uniformity of liquid processing in the surface of the substrate and among a plurality of substrates.

In order to solve the above technical problem, the present invention provides a substrate processing apparatus, comprising:
a processing tank, for accommodating a plurality of substrates arranged in a column in a horizontal direction, and storing processing liquid for immersing the plurality of substrates, the arrangement direction of the substrates being defined as a Y direction, and a horizontal direction parallel to a main surface of the substrate being defined as an X direction, and the X direction and the Y direction being perpendicular to each other;
a bubbler, disposed in the processing tank, and positioned below the plurality of substrates, for supplying bubbles into the processing liquid, the bubbler including:
a bubble plate, facing the plurality of substrates, the bubble plate having a plurality of opening holes thereon;
a bubble chamber, for providing gas to the plurality of opening holes;
wherein, the inside of the bubble chamber is divided into at least two gas channels independent of each other, and the flow rate of gas supply of at least two gas channels is independently controlled.

In order to solve the above technical problem, the present invention also provides a substrate processing apparatus, comprising:
a processing tank, for accommodating a plurality of substrates arranged in a column in a horizontal direction, and storing processing liquid for immersing the plurality of substrates, the arrangement direction of the substrates being defined as a Y direction, and a horizontal direction parallel to a main surface of the substrate being defined as an X direction, and the X direction and the Y direction being perpendicular to each other;
a bubble box, disposed in the processing tank, and positioned below the plurality of substrates, for supplying bubbles into the processing liquid, the bubble box including:
a bubble plate, facing the plurality of substrates, the bubble plate having a plurality of opening holes thereon;
a bubble chamber, for providing gas to the plurality of opening holes;
wherein, the plurality of opening holes are non-uniformly distributed on the bubble plate.

In order to solve the above technical problem, the present invention also provides a substrate processing apparatus, comprising:
a processing tank, for accommodating a plurality of substrates arranged in a column in a horizontal direction, and storing processing liquid for immersing the plurality of substrates;
a bubbler, disposed in the processing tank, and positioned below the plurality of substrates, for supplying bubbles into the processing liquid, the bubbler having a gas inlet, the gas inlet being provided with a baffle plate, the baffle plate being provided in a gas flow direction, for uniformly diffusing the gas supplied into the bubbler through the gas inlet in the bubbler.

### BRIEF DESCRIPTION OF THE DRAWINGS

FIG. 1 shows a perspective view of a substrate processing apparatus according to embodiment 1 of the present invention;

FIG. 2 shows a top view of a substrate processing apparatus according to embodiment 1 of the present invention;

FIG. 3 shows a cross-sectional view of FIG. 2 along the A-A direction;

FIG. 4 shows a cross-sectional view of FIG. 2 along the B-B direction;

FIGS. 5a to 5d show schematic views of a positional relationship between a liquid supply portion and a gas supply portion according to embodiment 1 of the present invention;

FIG. 6 shows a partial enlarged view at position C in FIG. 2;

FIG. 7 shows a perspective view of a gas supply portion according to embodiment 1 of the present invention;

FIG. 8 shows a cross-sectional view of FIG. 7 along the X direction;

FIGS. 9a to 9c show schematic views of gas channels inside the bubble chamber according to embodiment 1 of the present invention;

FIG. 10 shows a schematic view of an etched region divided into the X direction on a substrate;

FIG. 11 shows a perspective view of a bubbler according to embodiment 2 of the present invention;

FIG. 12 a shows a cross-sectional view of FIG. 11 along the X direction, wherein, no partition plate is provided in the bubble chamber;

FIG. 12 b shows a cross-sectional view of FIG. 11 along the X direction, wherein, partition plates are provided in the bubble chamber;

FIGS. 13a to 13c show schematic views of the opening hole regions on the bubble plate according to embodiment 2 of the present invention;

FIG. 14 shows a schematic view of the opening hole regions and the opening hole densities on the bubble plate according to an embodiment of the present invention;

FIG. 15 shows a schematic view of the opening hole regions and the opening hole densities on the bubble plate according to another embodiment of the present invention;

FIG. 16 shows a schematic view of the opening hole regions and the opening hole densities on the bubble plate according to yet another embodiment of the present invention;

FIG. 17 shows a schematic view of substrate groups in which a plurality of substrates are divided into the Y direction;

FIGS. 18a to 18c show schematic views of a plurality of columns of opening holes in one opening hole region according to embodiment 2 of the present invention;

FIG. 19 shows a perspective view of a bubbler according to embodiment 3 of the present invention;

FIG. 20 shows a cross-sectional view of FIG. 19 along the X direction;

FIG. 21a shows a cross-sectional view of a bubbler according to embodiment 4 of the present invention, wherein, baffle plates are provided at the gas inlet;

FIG. 21b shows a cross-sectional view of a bubbler, wherein, no baffle plate is provided at the gas inlet;

FIG. 22 is a top view of a bubbler according to embodiment 4 of the present invention;

FIG. 23 a shows a simulated curve of gas velocity distribution along the Y direction of the bubbler shown in FIG. 21a;

FIG. 23 b shows a simulated curve of gas velocity distribution along the Y direction of the bubbler shown in FIG. 21b;

FIG. 24 a shows a simulated curve of gas velocity distribution along the X direction of the bubbler shown in FIG. 21a;

FIG. 24 b shows a simulated curve of gas velocity distribution along the X direction of the bubbler shown in FIG. 21b;

FIG. 25 is a bottom view of a bubbler according to embodiment 5 of the present invention;

FIG. 26 is a cross-sectional view of a bubbler along the X direction according to an embodiment in embodiment 5 of the present invention;

FIG. 27 is a cross-sectional view of a bubbler along the X direction according to another embodiment in embodiment 5 of the present invention;

FIG. 28 shows a schematic view of the bubbling from the bubble generating pipes in the prior art.

### PREFERRED EMBODIMENTS OF THE INVENTION

Hereinafter, the embodiments of the present invention will be described with specific embodiments, and other advantages and effects of the present invention will be readily apparent to those skilled in the art from the disclosure of the present specification. The present invention can also be embodied or applied by other different and specific embodiments, and various details in this specification can also be modified or changed based on different viewpoints and applications without departing from the spirit of the present invention.

It should be noted that the drawings provided in the present embodiments illustrate the basic concept of the present invention only in a schematic manner. Although only components related to the present invention are shown in the drawings and are not drawn according to the number, shape and size of the components in actual implementation, the form, number and proportion of each component in actual implementation may be arbitrarily changed, and the layout of the components may be more complicated.

### First Embodiment

In the present application, the substrate processing apparatus performs batch processing such as cleaning or etching on a plurality of substrates with the processing liquid. The type and temperature of the processing liquid are not particularly limited. For example, the processing liquid may be the cleaning liquid such as SC-1 (standard cleaning liquid No. 1), SC-2 (standard cleaning liquid No. 2) or H₂SO₄ (sulfuric acid) for cleaning the substrates. The processing liquid may also be the cleaning liquid such as DIW (deionized water) or UPW (ultrapure water) for cleaning the substrates. The processing liquid may also be the etching liquid such as BHF (buffered hydrofluoric acid) or H₃PO₄ (high-temperature phosphoric acid) for etching the substrates.

In the present embodiment, a phosphoric acid etching process performed by a substrate processing apparatus will be described as an example. Specifically, the substrate processing apparatus selectively perform a wet etching on the silicon nitride as a masking layer in the pattern surface of the substrates by using the high-temperature phosphoric acid solution (at a temperature of about 160° C.), so as to accurately transfer the pattern on the photolithography mask to the surface of the substrates.

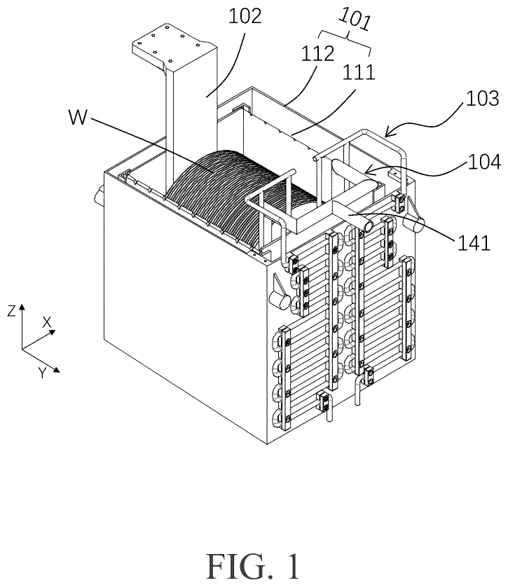

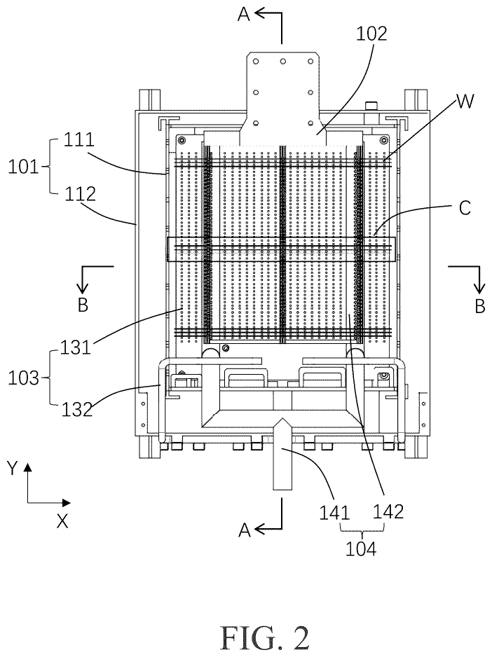

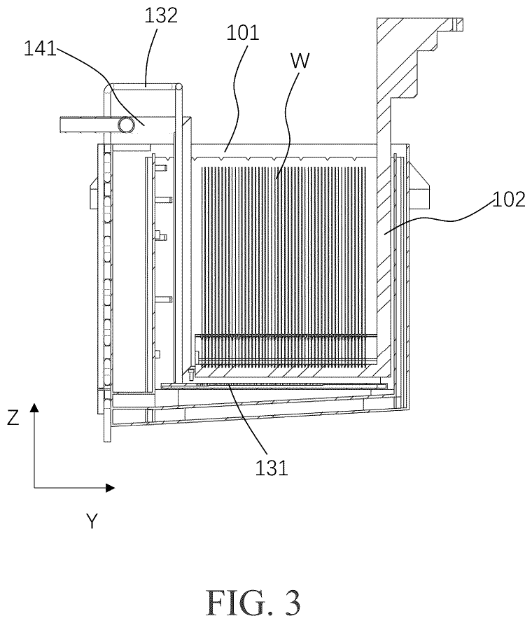

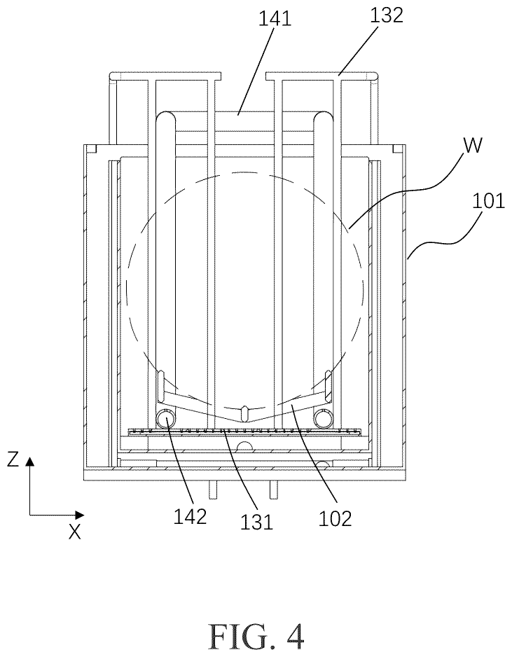

FIG. 1 is a perspective view of a substrate processing apparatus according to the first embodiment. FIG. 2 is a top view of a substrate processing apparatus according to the first embodiment. FIG. 3 is a cross-sectional view of FIG. 2 along the A-A direction. FIG. 4 is a cross-sectional view of FIG. 2 along the B-B direction.

As shown in FIGS. 1 to 4, the substrate processing apparatus comprises a processing tank 101, a substrate holding portion 102, a gas supply portion 103 and a liquid supply portion 104.

The processing tank 101 is used to store the processing liquid and accommodate a plurality of substrates W. The processing liquid stored in the processing tank 101 is, for example, the phosphoric acid solution, and the temperature of the phosphoric acid solution is 140° to 160°. In the present embodiment, the processing tank 101 comprises an inner tank 111 and an outer tank 112, and the inner tank 111 is located in the outer tank 112. Both the bottom wall and the side wall of the inner tank 111 and the inner wall of the outer tank 112 have a certain interval, and the processing liquid in the inner tank 111 can overflow into the outer tank 112. The processing liquid in the outer tank 112 surrounds the inner tank 111, and can play a certain heat preservation effect on the processing liquid in the inner tank 111, thereby reducing the temperature loss of the processing liquid, reducing the energy consumption, and improving the stability of the process at the same time.

It should be noted that, in other embodiments, the outer tank 112 may also be provided around the upper periphery of the inner tank 111, and used only as an overflow tank.

The substrate holding portion 102 is used to hold a plurality of substrates W in the processing tank 101, and the plurality of substrates W are arranged in a column along the horizontal direction at a predetermined interval p in a vertical posture. The predetermined interval p is, for example, 5 mm. Herein, the arrangement direction of the substrates is defined as the Y direction, the horizontal direction parallel to the main surface of the substrates is defined as the X direction, and the X direction and the Y direction are perpendicular. The direction perpendicular to the plane in which the X direction and the Y direction are located is defined as the Z direction.

Furthermore, in the present embodiment, the substrate holding portion 102 is provided in the processing tank 101 so as to be liftable, that is, the substrate holding portion 102 has a function of simultaneously driving the plurality of substrates W to lift and lower in the processing tank 101. When the substrate liquid processing is performed, the substrate holding portion 102 drives the substrates W down into the processing tank 101, so as to immerse the substrates W in the processing liquid. After the substrate liquid processing is completed, the substrate holding portion 102 drives the substrates W to lift away from the processing tank 101. In another embodiment, the substrate holding portion 102 may be fixedly provided in the processing tank 101.

The gas supply portion 103 comprises a bubbler 131 and gas inlet pipelines 132. The bubbler 131 is provided in the processing tank 101 below the plurality of substrates W, and is used to supply bubbles into the processing liquid. The average diameter of bubbles generated by the bubbler 131 is d, wherein 30% p≤d≤95% p, and p is a predetermined interval between a plurality of substrates W. The gas inlet pipelines 132 are used to supply gas to the bubbler 131. At least a part of the pipelines of the gas inlet pipelines 132 is fixed on the outer wall of the processing tank 101 in the form of a coil, so that the gas in the gas inlet pipelines 132 can exchange heat with the processing liquid in the processing tank 101 before the gas is supplied to the processing liquid, thereby avoiding the temperature fluctuation of the processing liquid caused by an excessive temperature difference between the gas and the processing liquid, and thus affecting the etching effect of the substrates. In FIG. 1, a part of the gas inlet pipelines 132 is fixed on the outer wall of the outer tank 112 in the form of a serpentine coil.

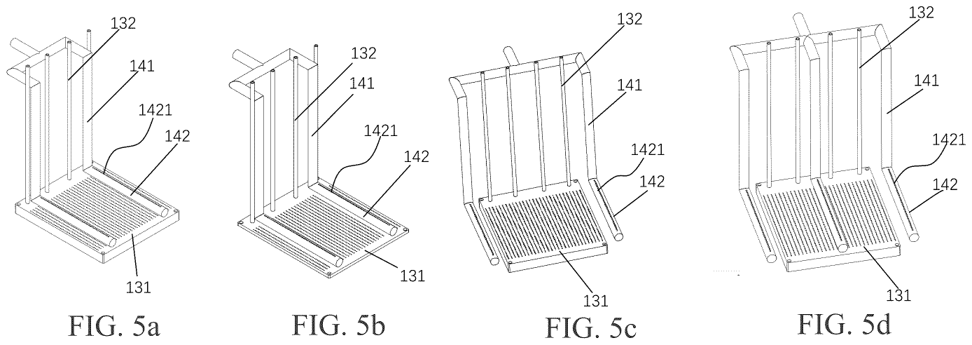

The liquid supply portion 104 comprises liquid inlet pipelines 141 and liquid ejection pipes 142. The liquid inlet pipeline 141 is used to supply the processing liquid to the liquid ejection pipe 142, for example, the phosphoric acid solution at 140° C. to 160° C. The liquid inlet pipeline 141 has a branch pipeline (not shown in the picture) connected to the outer tank 112, so as to circulate the processing liquid between the inner tank 111 and the outer tank 112. The liquid ejection pipes 142 are located between the bubbler 131 and the plurality of substrates W. The liquid ejection pipes 142 extend along the Y direction for supplying the processing liquid into the processing tank 101. With reference to FIGS. 5a to 5d, the liquid ejection pipes 142 are provided with a plurality of liquid outlets 1421 facing the substrates W, and the liquid outlets 1421 are at an included angle of 0 to 180 ° with respect to the vertical direction.

The liquid ejection pipes 142 may be disposed directly above and/or above the side of the bubbler 131. As shown in FIGS. 5a and 5b, two liquid ejection pipes 142 are provided, and the two liquid ejection pipes 142 are symmetrically distributed about the center of the substrates W and disposed directly above the bubbler 131. In FIG. 5a, the bubbler 131 has opening holes in the vertical projection region of the liquid ejection pipes 142; In FIG. 5b, the bubbler 131 does not have opening holes in the vertical projection region of the liquid ejection pipes 142. As shown in FIG. 5c, two liquid ejection pipes 142 are provided, and the two liquid ejection pipes 142 are symmetrically distributed with respect to the normal line of the substrates W and are provided above the side of the bubbler 131. As shown in FIG. 5d, three liquid ejection pipes 142 are provided, and among the three liquid ejection pipes 142, two liquid ejection pipes 142 located on the outer side are symmetrically distributed with respect to the center of the substrates W and are provided above the side of the bubbler 131, and the liquid ejection pipe 142 located in the middle is provided directly above the bubbler 131.

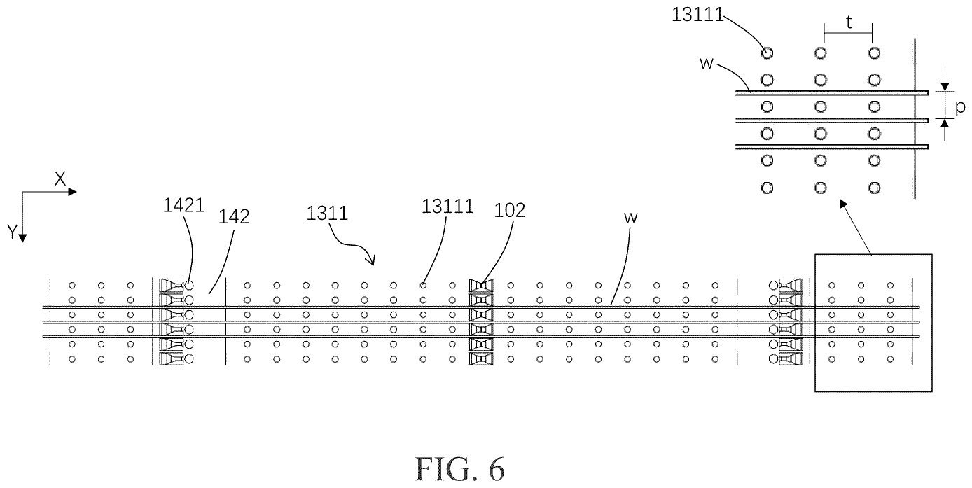

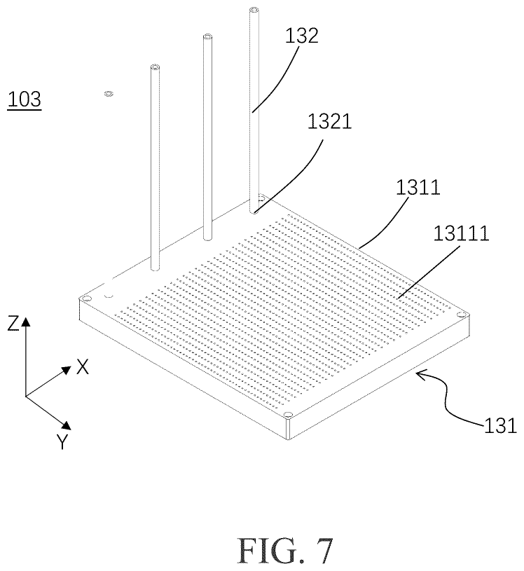

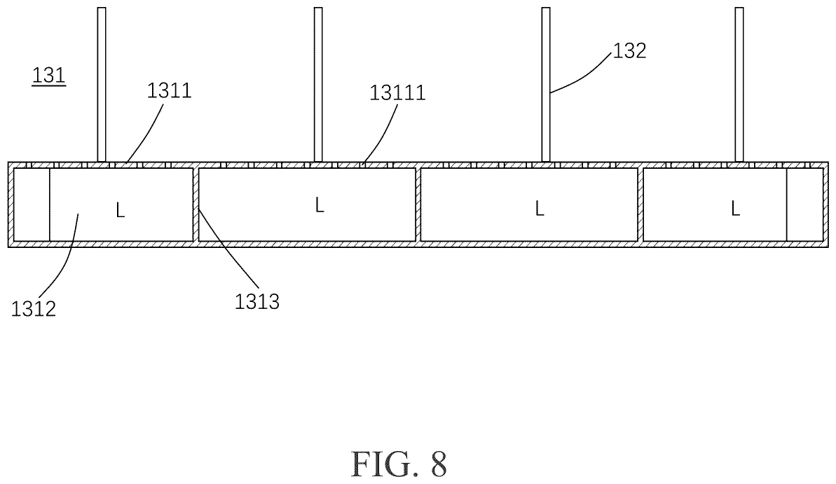

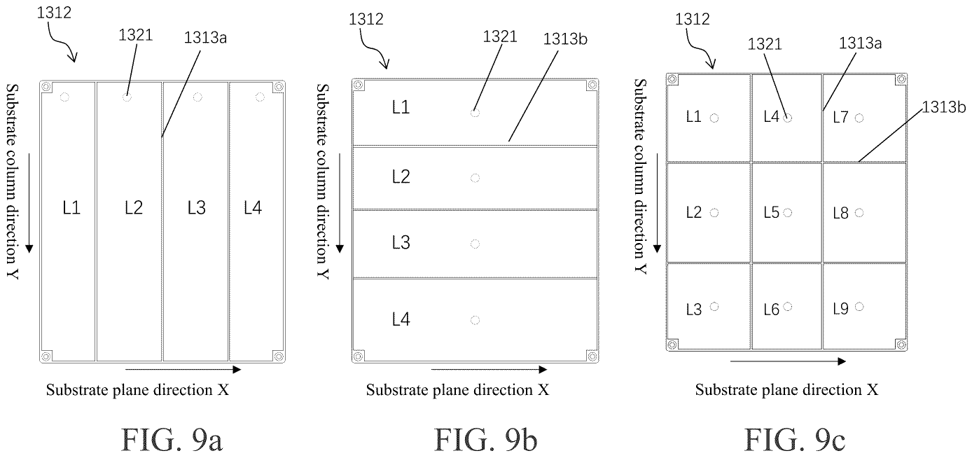

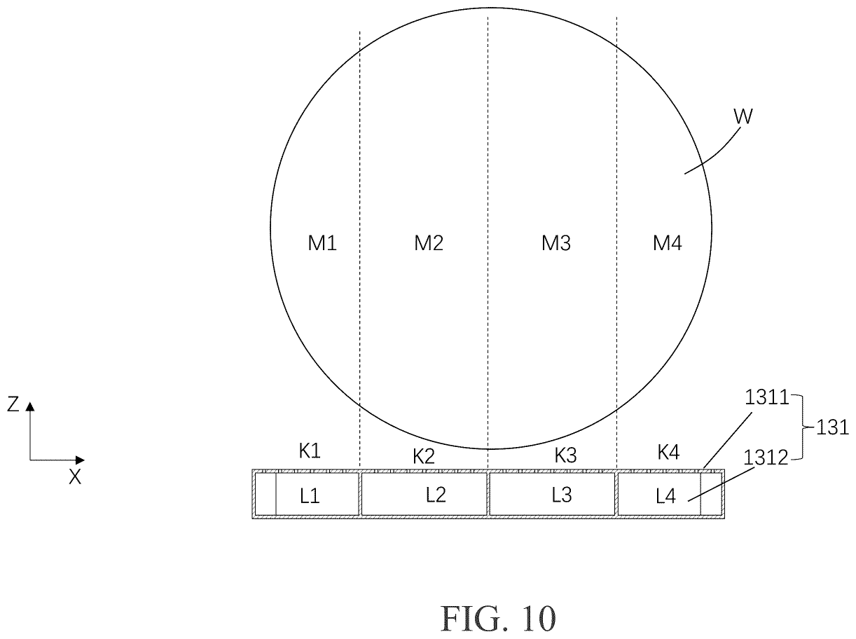

FIG. 6 is a partially enlarged view at position C in FIG. 2, showing the positional relationship between the opening holes in the bubbler and the substrates. FIG. 7 shows a perspective view of a bubbler. FIG. 8 shows a cross-sectional view of a bubbler along the X direction. FIGS. 9a-9c show schematic views of gas channels inside the bubble chamber. FIG. 10 shows a schematic view of an etching region divided into the X direction on the substrate.

Hereinafter, the configuration of the bubbler will be described with reference to FIGS. 6 to 10.

As shown in FIG. 7, the bubbler 131 is a flat bubble box 131. The top surface of the bubble box 131 is a bubble plate 1311 having a plurality of opening holes 13111. The bubble plate 1311 faces a plurality of substrates W, and a plurality of opening holes 13111 may be uniformly distributed or may not be uniformly distributed. In the present embodiment, a plurality of opening holes 13111 are arranged in N rows along the Y direction, and when viewed from above, a row of opening holes 13111 are provided between adjacent substrates W, and N is a positive integer. Specifically, N is usually not less than the number of substrates that the substrate holding portion 102 can support. As shown in FIG. 6, an interval between two opening holes 13111 adjacent to each other in the X direction is t, wherein, 30% p≤t≤4 p, and p is a predetermined interval between a plurality of substrates W. By arranging a row of opening holes 13111 between adjacent substrates W, the bubbles can better uniformly cover the entire surface of the substrates along the surface direction of the substrates (i.e., the X direction), avoid the bubble-free stirring in local regions of the substrates, and thus improve the uniformity in the surface of the substrates.

As shown in FIGS. 7 and 8, the internal space of the bubble box 131 forms a bubble chamber 1312 having at least two gas channels L, for supplying gas to a plurality of opening holes 13111 on the bubble plate 1311. As shown in FIG. 8, the bubble chamber 1312 has partition plates 1313 inside, and the partition plates 1313 divide the bubble chamber 1312 into at least two gas channels L. The flow rate of gas supply of at least two gas channels L is independently controlled. The partition plates 1313 may be detachable or fixed.

Each gas channel L is provided with a gas inlet pipeline 132 and a gas inlet 1321 respectively, and the gas inlet pipeline 132 communicates with the corresponding gas channel L through the gas inlet 1321. A flow control element (not shown in the picture), such as an MFC (mass flow controller), is arranged on the gas inlet pipeline 132, for adjusting the flow rate of gas supply in the corresponding gas channel L.

The inside of the bubble chamber 1312 is divided into at least two gas channels along the X-direction and/or the Y-direction. For example, as shown in FIG. 9a, the longitudinal partition plates 1313a extending along the Y direction are provided in the bubble chamber 1312, and the inside of the bubble chamber 1312 is divided into four gas channels L1-L4 along the X direction. As another example, as shown in FIG. 9b, the transverse partition plates 1313b extending along the X direction are provided in the bubble chamber 1312, and the inside of the bubble chamber 1312 is divided into four gas channels L1-L4 along the Y direction. As another example, as shown in FIG. 9c, the longitudinal partition plates 1313a extending along the Y direction and the transverse partition plates 1313b extending along the X direction are provided in the bubble chamber 1312, and the inside of the bubble chamber 1312 is divided into nine gas channels L1-L9 in a mesh along the X direction and the Y direction.

It should be noted that FIGS. 9a to 9c are merely examples, and are not used to limit the number and direction of division of gas channels and the relative size of each gas channel. For example, the partition plates may have included angles with the X direction or the Y direction to delineate inclined gas channels, or the partition plates may be circular or rectangular partition plates to delineate annular gas channels. For another example, referring to FIG. 9a, the widths of the gas channels L1 to L4 in the X direction are denoted as W1 to W4 respectively. In one embodiment, the inside of the bubble chamber 1312 may be divided into equal parts of gas channels L1-L4 along the X direction, that is, W1=W2=W3=W4, and in another embodiment, the inside of the bubble chamber 1312 may be divided into unequal parts of gas channels L1-L4 along the X direction, for example, W1=W4<W2=W3.

The independent control of the flow rate of gas supply of each gas channel is described in the division method of the bubble chamber shown in FIG. 9a. Referring to FIGS. 9a and 10, the bubble chamber 1312 divides the gas channels into L1 to L4 along the X direction, and similarly, the substrates W are divided into etching regions M1 to M4 corresponding to the gas channels L1 to L4 along the X direction. In the present embodiment, the bubbling behavior of the corresponding etching regions, such as the number of bubbles, is controlled by adjusting the flow rate of gas supply of the gas channels, so that the etching rate in each etching region on the substrates is the same, thereby improving the in-surface uniformity of the substrate etching. For example, the substrate is etched under the condition that the gas supply quantity of the gas channels L1 to L4 is the same, and the average etching rates V1 to V4 of the substrate etching regions M1 to M4 are respectively obtained. When the experimental result shows that V1=V4<V2=V3, the flow rate of gas supply of the gas channels L1 and L4 can be increased, the number of bubbles in the etching regions M1 and M4 can be increased, and the stir effect and quality transfer efficiency of the etching regions M1 and M4 can be improved, thereby improving the etching rate of the etching regions M1 and M4. Hence, V1=V2=V3=V4 can be obtained, and the purpose of improving the in-surface uniformity of the substrate etching can be further achieved.

### Second Embodiment

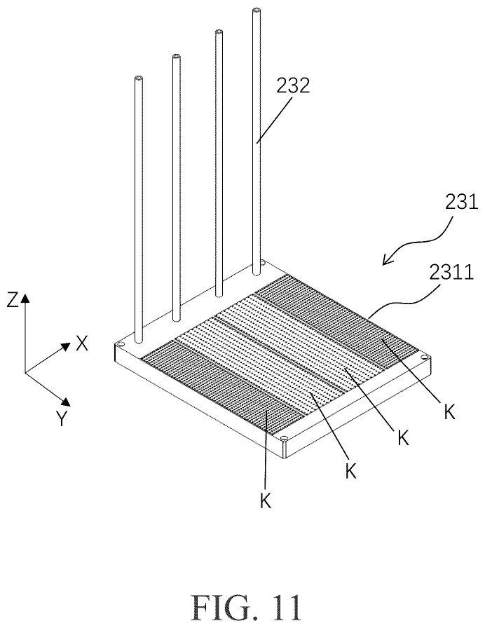

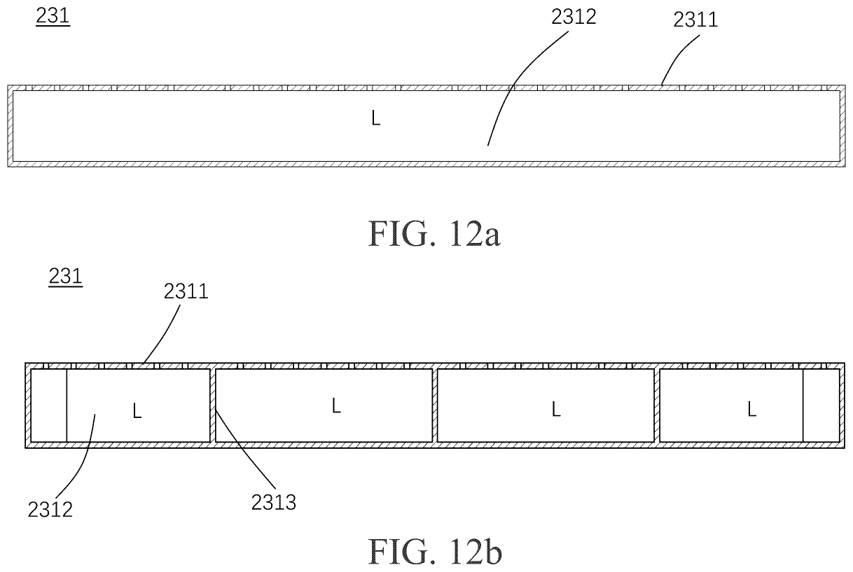

Please refer to FIGS. 11 to 15, the present embodiment provides a substrate processing apparatus, and compared with the first embodiment, the second embodiment is different from the structure of bubbler 231, and other structures are the same as the structures of the first embodiment, and will not be repeatedly described. The bubbler 231 comprises a bubble plate 2311 and a bubble chamber 2312. The gas inlet pipelines 232 communicate with the gas channels L inside the bubble chamber 2312, for supplying gas to the bubble plate 2311. In one embodiment, the internal space of the bubble chamber 2312 is not divided into regions and is a through gas channel L, as shown in FIG. 12a. In another embodiment, the internal space of the bubble chamber 2312 is provided with partition plates 2313, and the partition plates 2313 divide the internal space of the bubble chamber 2312 into at least two gas channels L. As shown in FIG. 12b, the flow rate of gas supply of at least two gas channels L is independently controlled, and the control mode of flow rate of specific gas supply of each gas channel can be described in the relevant description of the first embodiment.

In the present embodiment, at least two opening hole regions K are divided on the bubble plate 2311, and the opening hole densities of at least two opening hole regions K are set independently. It should be noted that, when the partition plates 2313 are provided in the bubble chamber 2312, the at least two opening hole regions K on the bubble plate 2311 may or may not correspond to at least two gas channels L in the bubble chamber 2312 one-to-one. In short, the region division of the bubble plate 2311 and the bubble chamber 2312 is relatively independent. In the present application, the region division of the bubble plate 2311 and the bubble chamber 2312 is based on the etching rate distribution in the surface of the substrates and the etching rate distribution among a plurality of substrates.

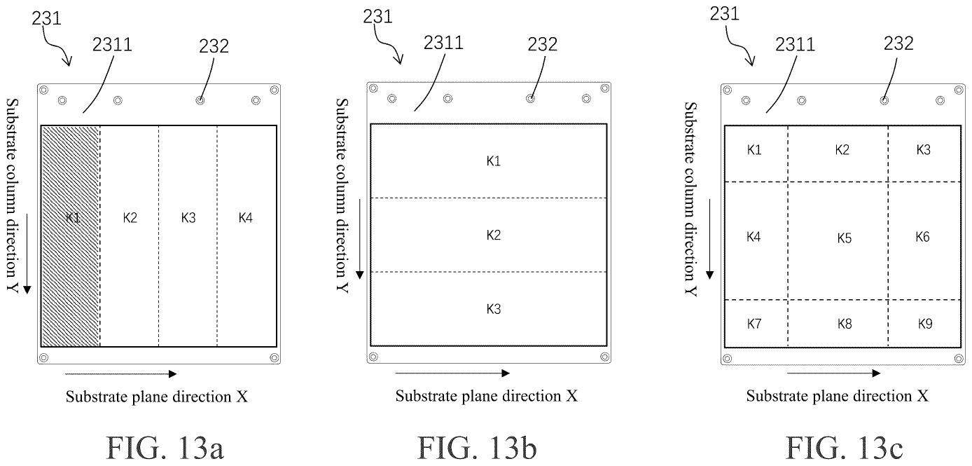

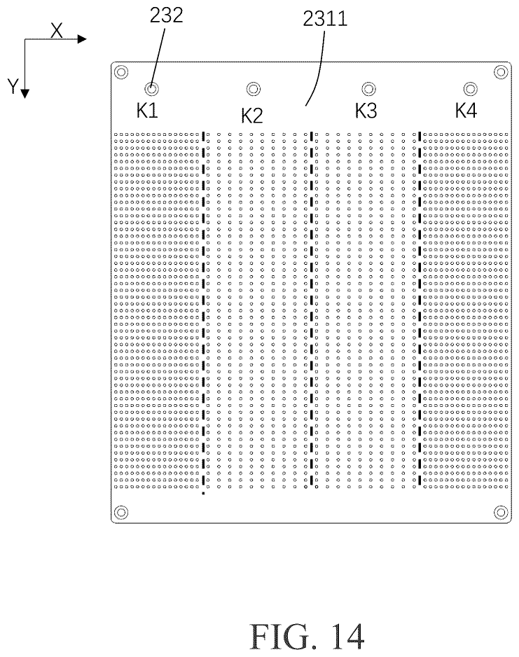

At least a part of the opening hole regions K on the bubble plate 2311 may be formed by a detachable movable panel having a plurality of opening holes, and the movable panel may be sealed and spliced in the corresponding opening hole regions. In the present embodiment, at least two opening hole regions K are divided on the bubble plate 2311 along the X direction and/or the Y direction. FIGS. 13a-13c show schematic views of the opening hole regions on the bubble plate 2311. As shown in FIG. 13a, the bubble plate 2311 is divided into four opening hole regions K1-K4 along the X direction, and all of the four opening hole regions K1-K4 extend along the Y direction. As shown in FIG. 13b, the bubble plate 2311 is divided into three opening hole regions K1-K3 along the Y direction, and all of the three opening hole regions K1-K3 extend along the X direction. As shown in FIG. 13c, the bubble plate 2311 is divided into nine opening hole regions K1-K9 along the X direction and the Y direction. Hereinafter, the independent setting of the opening hole density of each opening hole region of the bubble plate 2311 will be described with reference to FIGS. 14 to 16.

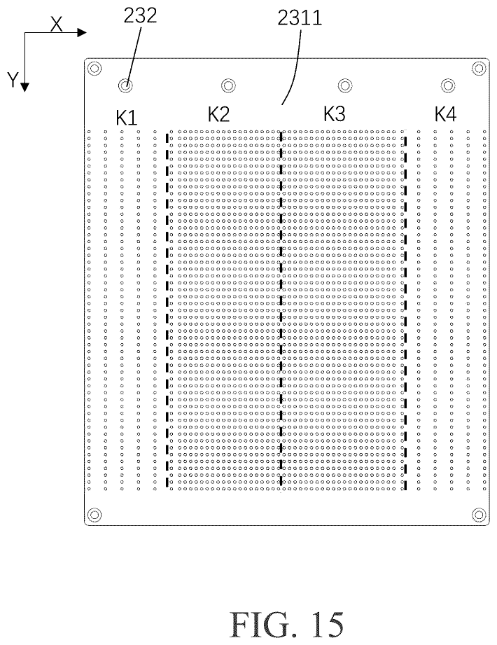

As shown in FIGS. 14 and 15, the bubble plate 2311 is divided into four opening hole regions K1 to K4 along the X direction, and the opening hole densities of the four opening hole regions K1 to K4 are denoted as Q1 to Q4 respectively. Similarly, with reference to FIG. 10, the substrate W is divided into etching regions M1 to M4 one-to-one corresponding to the opening hole regions K1 to K4 along the X direction. The bubbling behavior of the corresponding etching regions is adjusted by setting the opening hole densities of the opening hole regions, for example, the number of bubbles, so that the etching rate in each etching region on the substrate is the same, thereby improving the in-surface uniformity of the substrate etching.

For example, the substrate is etched under the condition that the opening hole densities of the four opening hole regions K1 to K4 are the same, so as to obtain the average etching rates V1 to V4 of the substrate etching regions M1 to M4. When the experimental result shows that V1=V4<V2=V3, the number of bubbles in the etching regions M1 and M4 can be increased by increasing the opening hole densities of the opening hole regions K1 and K4 (as shown in FIG. 14), and the stir effect and quality transfer efficiency of the etching regions M1 and M4 can be improved, thereby increasing the etching rates of the etching regions M1 and M4 on the substrate W. Hence, V1=V2=V3=V4 can be obtained, thereby achieving the purpose of improving the in-surface uniformity of the substrate etching. Similarly, when the experimental result shows that V1=V4>V2=V3, the number of bubbles at the positions of the etching regions M2 and M3 can be increased by increasing the opening hole densities of the opening hole regions K2 and K3 (as shown in FIG. 15), and the stir effect and quality transfer efficiency of the etching regions M2 and M3 on the substrate W can be improved, thereby increasing the etching rate of the etching regions M2 and M3 and making V1=V2=V3=V4, thereby achieving the purpose of improving the in-surface uniformity of the substrate etching.

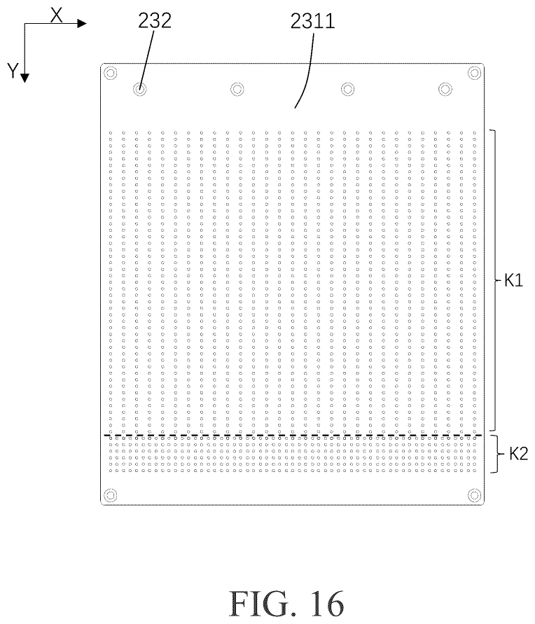

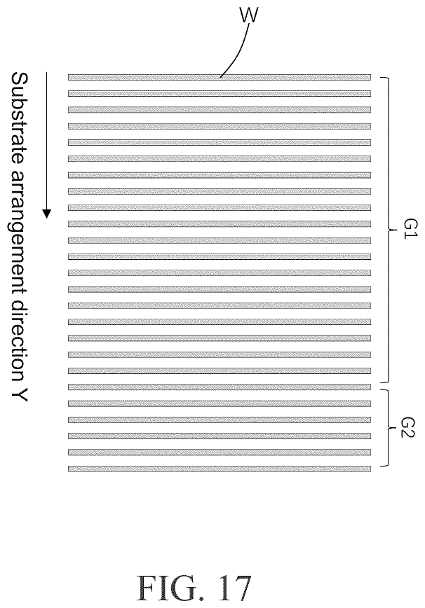

As shown in FIG. 16, two opening hole regions K1 and K2 are divided into the Y direction on the bubble plate 2311, and the opening hole densities of the two opening hole regions K1 and K2 are denoted as Q1 and Q2 respectively. At the same time, with reference to FIG. 17, a plurality of substrates W are divided into substrate groups G1 and G2 one-to-one corresponding to the opening hole regions K1 and K2 along the arrangement direction Y. The bubbling behavior at each substrate group, for example, the number of bubbles, is adjusted by setting the opening hole densities of the opening hole regions, so that the etching rate of each substrate group is the same, thereby improving the uniformity between the substrates by the substrate etching.

For example, the substrate is etched under the condition that the opening hole densities of the two opening hole regions K1 and K2 are the same, and the average etching rates V1 and V2 of the substrate groups G1 and G2 can be obtained respectively. When the experimental result shows that V1>V2, the number of bubbles supplied to the substrate group G2 can be increased by increasing the opening hole density of the opening hole region K2 (as shown in FIG. 16), and the stir effect and quality transfer efficiency of the region where the substrate group G2 is located can be improved, thereby improving the etching rate of the substrate group G2. V1=V2 can be obtained, thereby achieving the purpose of improving the inter-sheet uniformity of the substrate etching.

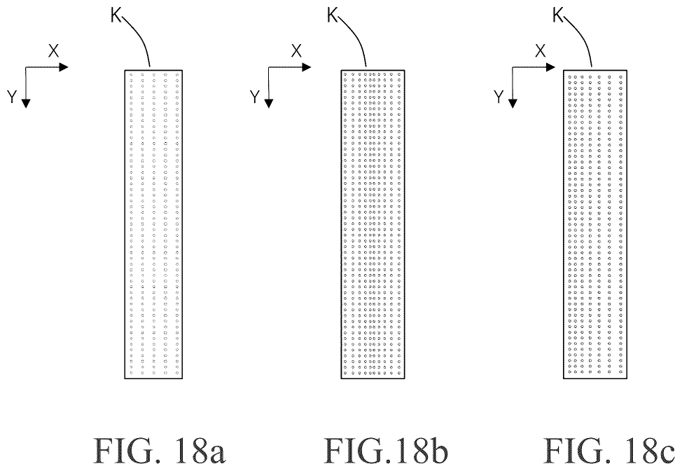

In the present application, the density change in the opening hole regions mainly refers to changing the interval between adjacent opening holes along the X direction in each opening hole region. Specifically, the interval between adjacent opening holes along the X direction in each opening hole region may be equal or partially unequal. In the present embodiment, for example, FIGS. 18a to 18c show three schematic views of a plurality of opening holes in one opening hole region are arranged in a plurality of columns along the X direction, and the column pitch of a plurality of columns of opening holes along the X direction may be equal or partially unequal. As shown in FIG. 18a, the opening hole region K has five columns of opening holes, and the column pitch between the five columns of opening holes is equal. As shown in FIG. 18b, there are ten columns of opening holes in the opening hole region K, and the column pitch of the ten columns of opening holes gradually increases from the center towards the outside. As shown in FIG. 18c, there are seven columns of opening holes in the opening hole region K, the column pitch of the five columns of opening holes on the left side gradually increases from left to right, and the column pitch of the three columns of opening holes on the right side is equal.

It should be noted that, in another embodiment, a plurality of opening holes in the opening hole regions are not arranged in columns in the X direction. A plurality of opening holes in the opening hole regions form a plurality of rows of opening holes in the Y direction, and the interval between adjacent opening holes in each row of opening holes can be adjusted.

In addition, the opening hole densities of the opening hole regions and the flow rate of gas supply of the gas channels can be simultaneously adjusted, so as to improve the uniformity of the substrate etching. For example, in one embodiment, four opening hole regions K1-K4 are divided on the bubble plate 2311 along the X direction as shown in FIG. 13a. At the same time, four gas channels L1 to L4 are divided into the bubble chamber 2322 along the X direction as shown in FIG. 12b. Referring to FIG. 10, the four gas channels L1 to L4 correspond to the four opening hole regions KI to K4 one-to-one. Assuming that the opening hole densities of the four opening hole regions K1 to K4 are the same, the etching rates of different etching regions on the corresponding substrates W are adjusted only by adjusting the flow rate of gas supply of the four gas channels L1 to L4, which is constrained by the upper limit value of the flow rate of gas supply. This is because continuously increasing the flow rate of gas supply after the flow rate of gas supply reaches the upper limit value, may make the average diameter of bubbles exceed the predetermined range. For example, if the flow rate of gas supply is too large, although the amount of bubbles is large, the coalescence between bubbles is accelerated, which will increase the bubble size, that is, simply changing the flow rate of gas supply may lead to the uncontrollable bubble size. However, the bubble size is also one of the key factors that determine the uniformity of the substrate etching. Based on this, the flow rate of gas supply of the gas channels and the opening hole densities of the opening hole regions can be adjusted at the same time to exert the synergistic effect of the two, and the bubbling behavior, such as the number of bubbles, can be improved on the basis of the controllable bubble size, so that the substrate etching can obtain better in-surface and inter-sheet uniformity.

### Third Embodiment

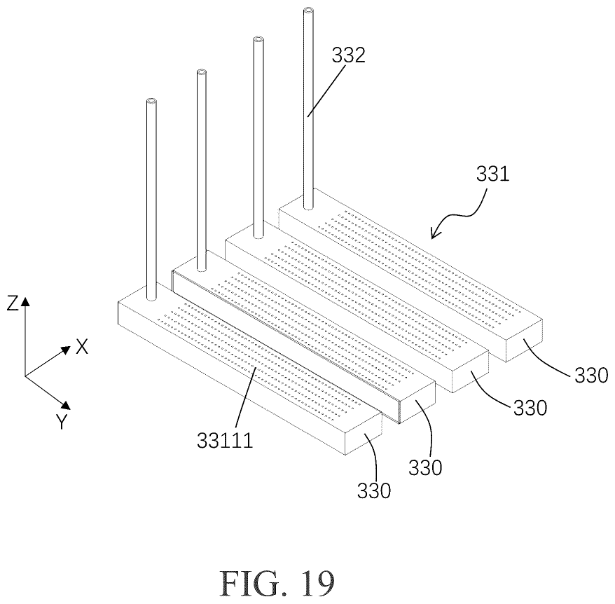

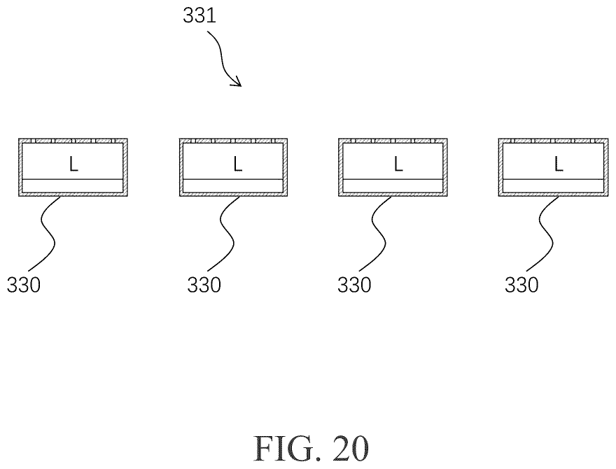

Please refer to FIGS. 19 and 20, the present embodiment provides a substrate processing apparatus, and the difference between the present embodiment and the first embodiment lies in the structure of bubbler 331, and the other structures are the same as the structures of the first embodiment, and will not be repeatedly described. FIG. 19 shows a perspective view of a bubbler in the present embodiment. FIG. 20 shows a cross-sectional view of a bubbler in the present embodiment. As shown in FIGS. 19 and 20, the bubbler 331 comprises at least two bubble pipes 330 having flat shapes, each bubble pipe has a plurality of opening holes 33111 on the top surface, each bubble pipe 330 constitutes at least one gas channel L inside, and the flow rate of gas supply of each gas channel L is independently controlled. The bubble pipes 330 may extend along the X direction or the Y direction.

In the present embodiment, the bubbler 331 has four bubble pipes 330. As shown in FIG. 19, the four bubble pipes 330 extend along the Y direction and are arranged in a column along the X direction. A gas channel L is formed inside each bubble pipe 330, and a gas inlet pipeline 332 is connected to each bubble pipe 330. The flow rate of gas supply within the respective bubble pipes 330 is regulated by a flow regulating element (e.g., MFC) arranged on the gas inlet pipelines 332. In other embodiments, partition plates (not shown in the picture) may be provided inside the bubble pipes 330, and at least two gas channels may be divided inside the bubble pipes 330 by the partition plates, and the flow rate of gas supply of each gas channel may be independently controlled.

In FIG. 19, the opening hole densities on the top surfaces of the four bubble pipes 330 are the same, and each bubble pipe 330 has five columns of opening holes distributed along the X direction. It should be noted that, the opening hole density of the top surface of each bubble pipe 330 is set independently. That is, the top surface of one bubble pipe 330 is equal to an opening hole region. The setting of opening hole density of the top surface of each bubble pipe 330 can refer to the related description of the setting of opening hole density of each opening hole region in the second embodiment, and will not be repeated herein.

The cross sections of the bubble pipes 330 are not limited to the rectangular shapes shown in FIG. 20, and may have any shape such as diamond shapes or ellipse shapes.

### Forth Embodiment

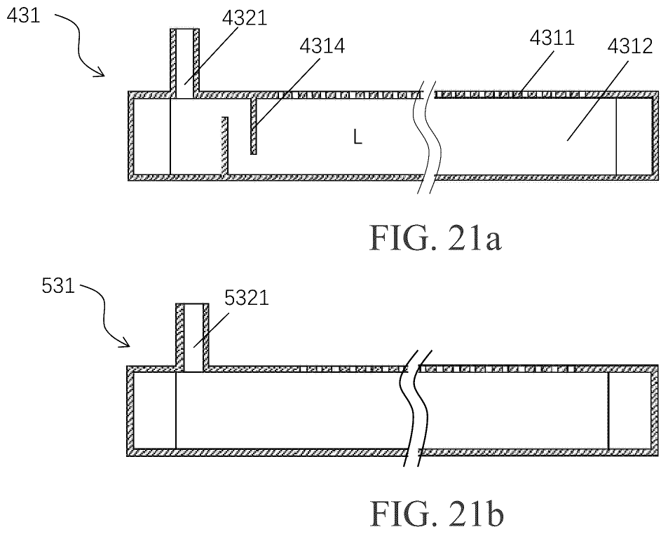

Please refer to FIGS. 21a to 24b, the present embodiment provides a substrate processing apparatus. Compared with the first embodiment, the difference of this embodiment is the structure of bubbler 431, and other structures are the same as the structures of the first embodiment, and will not be repeated. FIG. 21a shows a cross-sectional view of a bubbler in the fourth embodiment. The bubbler 431 comprises a bubble plate 4311 and a bubble chamber 4312 in which a gas channel L is formed, and the gas channel L is provided with a gas inlet 4321 for connecting to a gas inlet pipeline and supplying gas into the gas channel L. In the present embodiment, baffle plates 4314 are disposed at the gas inlet 4321, and the baffle plates 4314 are disposed in the gas flow direction, so as to uniformly diffuse the gas supplied into the bubble chamber 4312 through the gas inlet 4321 in the bubble chamber 4312. More specifically, the baffle plates 4314 are used to uniformly diffuse the gas supplied into the corresponding gas channel L through the gas inlet 4321 in the gas channel L.

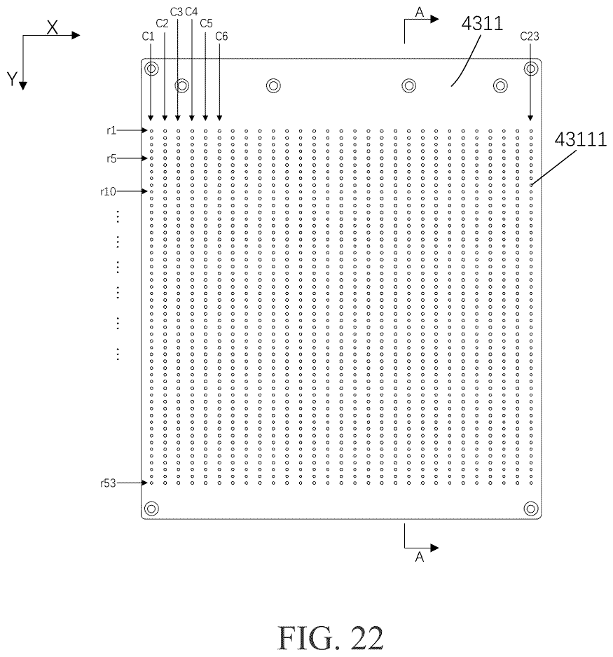

The applicant has performed a simulation analysis of the gas distribution of the bubbler 431 provided with the baffle plates 4314 at the gas inlet 4321 and the bubbler 531 not provided with the baffle plates respectively. The bubbler 431 shown in FIG. 21a is provided with baffle plates 4314 at the gas inlet 4321. FIG. 21b shows that there is no baffle plate provided at the gas inlet 5321 of the bubbler 531. Referring to FIG. 22, the opening holes form on the bubble plate of the bubbler 431 and the bubbler 531 are the same. Specifically, the opening holes 43111 on the bubble plate 4311 of the bubbler 431 are arranged in a matrix. In this embodiment, the bubble plate 4311 is provided with 53 rows of opening holes along the Y direction and 23 columns of opening holes along the X direction.

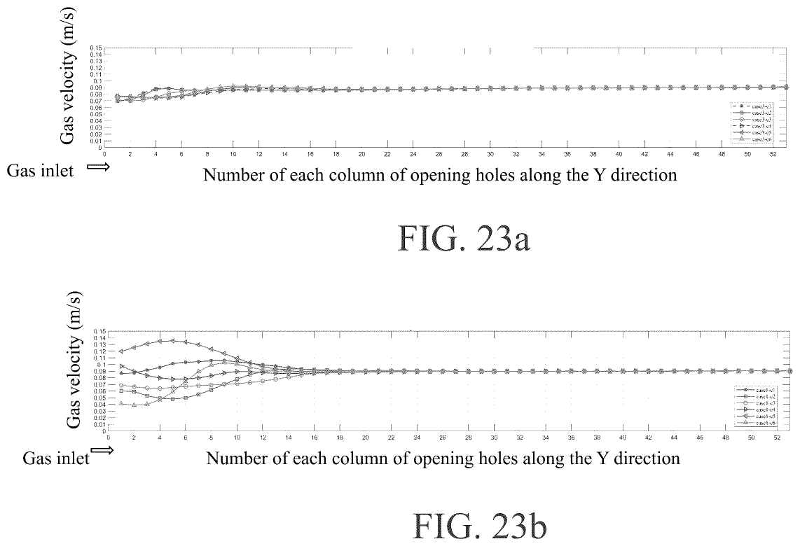

With reference to FIG. 22, FIG. 23a is a simulated curve of gas velocity distribution of six columns of opening holes C1 to C6 on the bubbler 431, and FIG. 23b is a simulated curve of gas velocity distribution of six columns of opening holes C1 to C6 on the bubbler 531. As can be seen from FIGS. 23a and 23b, the gas distribution along the Y direction on both the bubbler 431 and the bubbler 531 tends to be stable as the distance between the opening holes and the gas inlet increases. However, the six columns of opening holes C1 to C6 on the bubbler 431 start to converge and stabilize at approximately 0.09 m/s in the Y direction from the tenth row of opening holes (r10) on the gas inlet 4321 side, while the six columns of opening holes C1 to C6 on the bubbler 531 start to converge and stabilize at approximately 0.09 m/s in the Y direction from the sixteenth row of opening holes (r6) on the gas inlet 5321 side. Besides, the gas velocity fluctuation of the first 12 rows of opening holes (r1 to r12) in the six columns of opening holes C1 to C6 on the bubbler 431 is significantly smaller than the gas velocity fluctuation of the first 12 rows of opening holes (r1 to r12) in the six columns of opening holes C1 to C6 on the bubbler 531. As shown in FIG. 23b, the gas velocity fluctuation range of the first 12 rows of opening holes (r1 to r12) in the six columns of opening holes C1 to C6 on the bubbler 531 is 0.04 m/s to 0.14 m/s with a fluctuation range of 0.1 m/s, while the gas velocity fluctuation range of the first 12 rows of opening holes (r1 to r12) in the six columns of opening holes C1 to C6 on the bubbler 431 is 0.07 m/s to 0.09 m/s with a fluctuation range of only 0.02 m/s. Therefore, the bubbler 431 adds the baffle plates 4314 at the gas inlet 4321, which can significantly improve the uniformity of the gas velocity ejected from the opening holes on the bubble plate 4311 along the Y direction.

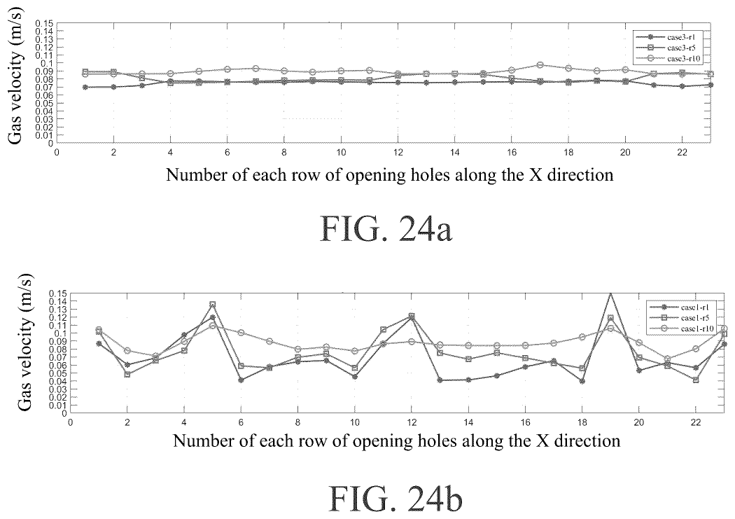

With reference to FIG. 22, FIG. 24a is a simulation curve of gas velocity distribution of the first row of opening holes r1, the fifth row of opening holes r5, and the tenth row of opening holes r10 on the bubbler 431 near the gas inlet 4321 side, and FIG. 24b is a simulation curve of gas velocity distribution of the first row of opening holes r1, the fifth row of opening holes r5, and the tenth row of opening holes r10 on the bubbler 531 near the gas inlet 5321 side. As can be seen from FIGS. 24a and 24b, the gas velocity distribution of the three rows of opening holes (r1, r5, r10) on the bubbler 431 has good uniformity with a fluctuation range of 0.03 m/s, while the gas velocity distribution of the three rows of opening holes (r1, r5, r10) on the bubbler 531 has poor uniformity with a fluctuation range of 0.11 m/s. Therefore, the bubbler 431 adds the baffle plates 4314 at the gas inlet 4321, which can significantly improve the uniformity of the gas velocity ejected from the opening holes on the bubble plate 4311 along the X direction.

Based on the above analysis, disposing the baffle plates 4314 at the gas inlet 4321 is beneficial to uniformly diffuse the gas in the bubble chamber 4312, and eliminates the phenomenon of uneven etching in the local regions of the substrate caused by the fluctuation of the gas flow rate at the gas inlet 4321 of the bubbler 431.

### Fifth Embodiment

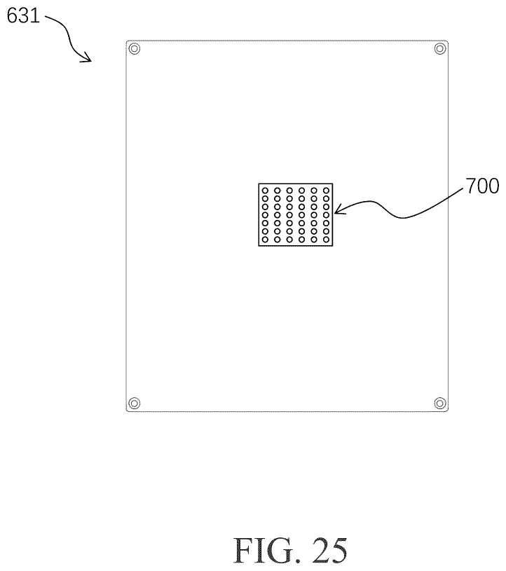

Please refer to FIGS. 25 to 27, the present embodiment provides a substrate processing apparatus. Compared with the first embodiment, this embodiment is different in the structure of bubbler 631, and other structures are the same as the structures of the first embodiment, and will not be repeatedly described. As shown in FIGS. 25 to 27, a purge member 700 is provided below the bubbler 631, for stirring the processing liquid below the bubbler 631 and preventing the formation of a stagnant water region below the bubbler 631.

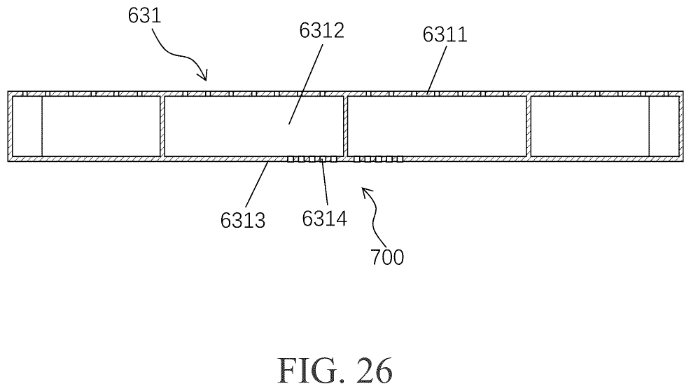

In one embodiment, as shown in FIG. 26, the bubbler 631 comprises a bubble chamber 6312, a bubble plate 6311 located at the top of the bubble chamber 6312, and a bottom plate 6313 located at the bottom of the bubble chamber 6312. Purge holes 6314 are arranged in a central region of the bottom plate 6313, and the purge holes 6314 communicate with the bubble chamber 6312 to form the purge member 700, for stirring the processing liquid below the bubbler 631.

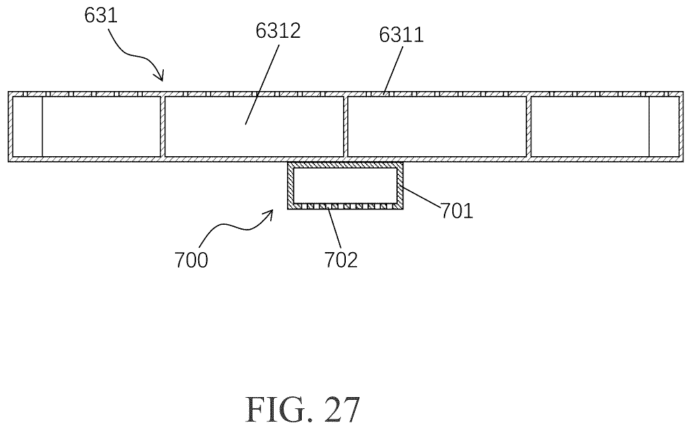

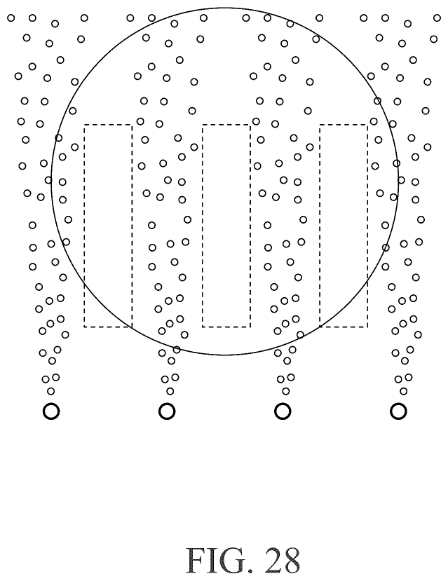

In another embodiment, as shown in FIG. 27, a purge member 700 is provided below the bubbler 631, and the purge member 700 comprises a housing 701 whose inside is hollow and a purge pipeline (not shown in the picture). The lower surface of the housing 701 is provided with openings 702. The purge pipeline communicates with the inside of the housing 701, for supplying gas to the inside of the housing 701, thereby stirring the processing liquid below the bubbler 631.

The above embodiments are merely illustrative of the principles and efficacies of the present invention, and are not intended to limit the present invention. Anyone skilled in the art can make modifications or changes to the above-described embodiments without departing from the spirit and scope of the present invention. Hence, all equivalent modifications or changes made by those skilled in the art without departing from the spirit and technical ideas disclosed herein should still be covered by the claims of the present invention.

1. A substrate processing apparatus, comprising:
a processing tank, for accommodating a plurality of substrates arranged in a column in a horizontal direction, and storing processing liquid for immersing the plurality of substrates, the arrangement direction of the substrates being defined as a Y direction, a horizontal direction parallel to a main surface of the substrate being defined as an X direction, and the X direction and the Y direction being perpendicular to each other;
a bubbler, disposed in the processing tank, and positioned below the plurality of substrates, for supplying bubbles into the processing liquid, the bubbler including:
a bubble plate, facing the plurality of substrates, the bubble plate having a plurality of opening holes thereon;
a bubble chamber, for providing gas to the plurality of opening holes;
wherein, the inside of the bubble chamber is divided into at least two gas channels independent of each other, and the flow rate of gas supply of the at least two gas channels is independently controlled.

2. (canceled)

3. The substrate processing apparatus according to claim 1, wherein the plurality of opening holes are arranged in N rows along the Y direction, and when viewed from above, a row of opening holes is provided between adjacent substrates, and N is a positive integer.

4. The substrate processing apparatus according to claim 3, wherein among the plurality of opening holes, the interval between two adjacent opening holes in the X direction is t, the plurality of substrates are arranged in a column at a predetermined interval p, and 30% p≤t≤4 p.

5. The substrate processing apparatus according to claim 1, wherein the average diameter of the bubbles generated by the bubbler is d, the plurality of substrates are arranged in a column at a predetermined interval p, and 30% p≤d≤95% p.

6. (canceled)

7. The substrate processing apparatus according to claim 1, wherein the plurality of opening holes are non-uniformly distributed.

8. The substrate processing apparatus according to claim 7, wherein the bubble plate is divided into at least two opening hole regions, and the opening hole densities of the at least two opening hole regions are independently set.

9. (canceled)

10. The substrate processing apparatus according to claim 8, wherein the interval between two adjacent opening holes along the X direction in each opening hole region is equal or at least partially unequal.

11. The substrate processing apparatus according to claim 8, wherein at least a part of the opening hole regions on the bubble plate is constituted by a detachable movable panel having a plurality of opening holes.

12. The substrate processing apparatus according to claim 1, wherein the bubbler comprises a bubble box having a flat shape, the top surface of the bubble box constitutes the bubble plate, the inside of the bubble box constitutes the bubble chamber, and a partition plate is provided in the bubble chamber, and the partition plate divides the bubble chamber into at least two gas channels.

13. The substrate processing apparatus according to claim 1, wherein the bubbler comprises at least two bubble pipes having flat shapes, the top surfaces of the at least two bubble pipes collectively form the bubble plate, the inside of the at least two bubble pipes collectively form the bubble chamber, the inside of each bubble pipe form at least one gas channel, the top surface of each bubble pipe has a plurality of opening holes.

14. The substrate processing apparatus according to claim 13, wherein a partition plate is provided in the bubble pipe, and the partition plate divides the inside of the bubble pipe into at least two gas channels.

15. The substrate processing apparatus according to claim 13, wherein the opening hole density of the top surface of each bubble pipe is set independently.

16. The substrate processing apparatus according to claim 1, wherein at least two gas channels are respectively configured with a gas inlet for supplying gas into the corresponding gas channel, and
wherein the substrate processing apparatus further comprises a gas supply pipeline that is connected to the gas inlet for supplying gas to the gas inlet, at least a part of the pipeline of the gas supply pipeline is fixed on the outer wall of the processing tank in the form of a coil for heat exchange between the gas in the gas supply pipeline and the processing liquid in the processing tank.

17. (canceled)

18. (canceled)

19. (canceled)

20. The substrate processing apparatus according to claim 1, further comprising a liquid ejection pipe, wherein the liquid ejection pipe is disposed below the plurality of substrates and extends along the Y direction for supplying the processing liquid into the processing tank, the liquid ejection pipe is provided with a plurality of liquid outlets facing the substrates and at an included angle of 0 to 180 ° with respect to the vertical direction.

21. The substrate processing apparatus according to claim 20, comprising two liquid ejection pipes, wherein both the liquid ejection pipes are symmetrically distributed about the center of the substrate, both the liquid ejection pipes are positioned directly above the bubbler, or both of the liquid ejection pipes are positioned above the side of the bubbler.

22. The substrate processing apparatus according to claim 20, wherein three liquid ejection pipes are provided, the three liquid ejection pipes are distributed at equal intervals, two liquid ejection pipes located outside are distributed symmetrically about the center of the substrate and are located above the side of the bubbler, and the liquid ejection pipe located in the middle is located directly above the bubbler.

23. The substrate processing apparatus according to claim 1, further comprising a purge member, wherein the purge member is disposed below the bubbler for stirring the processing liquid below the bubbler.

24. A substrate processing apparatus, comprising:
a processing tank, for accommodating a plurality of substrates arranged in a column along a horizontal direction and storing processing liquid for immersing the plurality of substrates, the arrangement direction of the substrates being defined as a Y direction, a horizontal direction parallel to a main surface of the substrate being defined as an X direction, and the X direction and the Y direction being perpendicular to each other;
a bubble box, disposed in the processing tank, and positioned below the plurality of substrates, for supplying bubbles into the processing liquid, the bubble box including:
a bubble plate, facing the plurality of substrates, the bubble plate having a plurality of opening holes thereon;
a bubble chamber, for providing gas to the plurality of opening holes;
wherein, the plurality of opening holes are non-uniformly distributed on the bubble plate.

25. The substrate processing apparatus according to claim 24, wherein the plurality of opening holes are arranged in N rows along the Y direction, and when viewed from above, a row of opening holes is provided between adjacent substrates, and N is a positive integer.

26. The substrate processing apparatus according to claim 24, wherein the bubble plate is divided into at least two opening hole regions, and the opening hole densities of the at least two opening hole regions are independently set.

27. (canceled)

28. (canceled)
